(19) United States
(12) Patent Application Publication
(10) Pub. No.: US 2019/0081215 A1
(43) Pub. Date: Mar. 14, 2019

(54) DEEP ULTRAVIOLET LIGHT EMITTING DEVICE

(71) Applicant: Nikkiso Co., Ltd, Tokyo (JP)

(72) Inventors: Tetsuhiko INAZU, Ishikawa (JP); Cyril PERNOT, Ishikawa (JP); Hisanori ISHIGURO, Ishikawa (JP)

(21) Appl. No.: 16/190,855

(22) Filed: Nov. 14, 2018

Related U.S. Application Data
(63) Continuation of application No. PCT/JP2017/014239, filed on Apr. 5, 2017.

(30) Foreign Application Priority Data
Jun. 6, 2016 (JP) 2016113017

(51) Int. Cl. H01L 33/44; H01L 33/22

(52) U.S. Cl. CPC H01L 33/44; H01L 33/32; H01L 33/22

(57) ABSTRACT

A deep ultraviolet light emitting device includes: a substrate having a first principal surface and a second principal surface opposite to the first principal surface; an active layer provided on the first principal surface of the substrate configured to emit a deep ultraviolet light; and a light extraction layer provided on the second principal surface of the substrate and made of a material having a refractive index for the deep ultraviolet light emitted by the active layer higher than that of the substrate and lower than that of the active layer.

### RELATED APPLICATION

Priority is claimed to Japanese Patent Application No. 2016-113017, filed on Jun. 6, 2016, the entire content of which is incorporated herein by reference.

### BACKGROUND OF THE INVENTION

### 1. Field of the Invention

The present invention relates to deep ultraviolet light emitting devices.

### 2. Description of the Related Art

Nowadays, semiconductor light emitting devices such as light emitting diodes and laser diodes that emit blue light have been in practical use. Development of light emitting devices that output deep ultraviolet light having a shorter wavelength has also been pursued. Deep ultraviolet light has sterilization capability. Semiconductor light emitting devices capable of outputting deep ultraviolet light have attracted attention as a mercury free sterilization light source in medical and food processing fronts. A light emitting device for emitting deep ultraviolet light includes an aluminum gallium nitride (AlGaN) based n-type clad layer, active layer, p-type clad layer, etc. stacked successively on a substrate.

Light emitting devices capable of rotating a light emitting body provided with a light source such as an LED are known.

### SUMMARY OF THE INVENTION

In this background, one illustrative purpose of the present invention is to provide a technology of increasing the light extraction efficiency of deep ultraviolet light emitting devices.

A deep ultraviolet light emitting device includes: a substrate having a first principal surface and a second principal surface opposite to the first principal surface; an active layer provided on the first principal surface of the substrate configured to emit a deep ultraviolet light; and a light extraction layer provided on the second principal surface of the substrate and made of a material having a refractive index for the deep ultraviolet light emitted by the active layer higher than that of the substrate and lower than that of the active layer.

According to this embodiment, the light extraction layer having a higher refractive index than the substrate is provided on the second principal surface of the substrate so that the deep ultraviolet light emitted by the active layer and arriving at the substrate can be guided to the light extraction layer without being totally reflected by the second principal surface. Further, a portion of the deep ultraviolet light arriving at the light extraction layer and not output outside by being reflected or scattered at the interface of the light extraction layer can be reflected by the second principal surface to remain in the light extraction layer. As a result, light components retuning to and absorbed by the active layer or the electrode of the light emitting device are reduced, and light components extracted outside by being reflected or scattered in the light extraction layer are increased. Further, by using a material having a lower refractive index than the active layer, the light extraction efficiency is prevented from being lowered due to too high a refractive index of the light extraction layer. Accordingly, the embodiment improves the light extraction efficiency of the deep ultraviolet light emitting device.

A deep ultraviolet light emitting device may further include a base layer provided between the first principal surface of the substrate and the active layer and made of a material having a refractive index for the deep ultraviolet light emitted by the active layer higher than that of the substrate and lower than that of the active layer.

The light extraction layer may be made of a material having an absorption coefficient of 5×10⁴/cm or smaller for the deep ultraviolet light emitted by the active layer.

The thickness of the light extraction layer may be 50 nm or larger.

The light extraction layer may have a light extraction surface formed with a micro-asperity structure.

The light extraction layer may be an aluminum gallium nitride (AlGaN)-based semiconductor material layer or an aluminum nitride (AlN) layer.

### BRIEF DESCRIPTION OF THE DRAWINGS

Embodiments will now be described, by way of example only, with reference to the accompanying drawings which are meant to be exemplary, not limiting, and wherein like elements are numbered alike in several Figures, in which:

FIG. 1 is a cross sectional view schematically showing a configuration of a deep ultraviolet light emitting device according to the embodiment;

FIG. 2 schematically shows a deep ultraviolet light emitting device according to a comparative example;

FIG. 3 schematically shows the benefit provided by the deep ultraviolet light emitting device according to the embodiment; and

FIG. 4 is a cross sectional view schematically showing a configuration of a deep ultraviolet light emitting device according to a variation.

### DETAILED DESCRIPTION OF THE INVENTION

The invention will now be described by reference to the preferred embodiments. This does not intend to limit the scope of the present invention, but to exemplify the invention.

A description will be given of an embodiment of the present invention with reference to the drawings. Like numerals are used in the description to denote like elements and the description is omitted as appropriate. To facilitate the understanding, the relative dimensions of the constituting elements in the drawings do not necessarily mirror the relative dimensions in the actual apparatus.

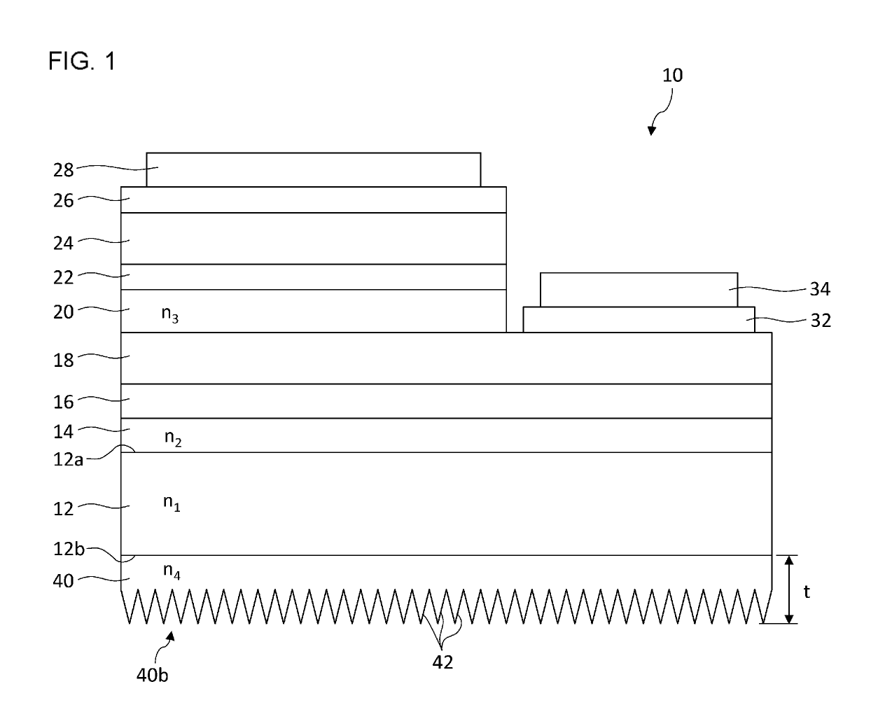

FIG. 1 is a cross sectional view schematically showing a configuration of a deep ultraviolet light emitting device 10 according to the embodiment. The deep ultraviolet light emitting device 10 includes a substrate 12, a first base layer 14, a second base layer 16, an n-type clad layer 18, an active layer 20, an electron block layer 22, a p-type clad layer 24, a p-type contact layer 26, a p-side electrode 28, an n-type contact layer 32, an n-side electrode 34, and a light extraction layer 40.

The deep ultraviolet light emitting device 10 is a semiconductor light emitting device configured to emit “deep ultraviolet light” having a central wavelength λ of about 355 nm or shorter. To output deep ultraviolet light having such a wavelength, the active layer 20 is made of an aluminum gallium nitride (AlGaN)-based semiconductor material having a band gap of about 3.4 eV or larger. In this embodiment, the case of emitting deep ultraviolet light having a central wavelength λ of about 280 nm is specifically discussed.

In this specification, the term “AlGaN-based semiconductor material” mainly refers to a semiconductor material containing aluminum nitride (AlN) and gallium nitride (GaN) and shall encompass a semiconductor material containing other materials such as indium nitride (InN). Therefore, “AlGaN-based semiconductor materials” as recited in this specification can be represented by a composition In_{1-x-y}AlₓGa_{y}N (0≤x+y≤1, 0≤x≤1, 0≤y≤1). The AlGaN-based semiconductor material shall contain AlN, GaN, AlGaN, indium aluminum nitride (InAlN), indium gallium nitride (InGaN), and indium aluminum gallium nitride (InAlGaN).

Of “AlGaN-based semiconductor materials”, those materials that do not substantially contain AlN may be distinguished by referring to them as “GaN-based semiconductor materials”. “GaN-based semiconductor materials” mainly contain GaN and InGaN and encompass materials that additionally contain a slight amount of AlN. Similarly, of “AlGaN-based semiconductor materials”, those materials that do not substantially contain GaN may be distinguished by referring to them as “AlN-based semiconductor materials”. “AlN-based semiconductor materials” mainly contain AlN and InAlN and encompass materials that additionally contain a slight amount of GaN.

The substrate 12 is a sapphire (Al₂O₃) substrate. The substrate 12 includes a first principal surface 12a and a second principal surface 12b opposite to the first principal surface 12a. The first principal surface 12a is a principal surface that is a crystal growth surface. For example, the first principal surface 12a is the (0001) plane of the sapphire substrate. For example, the first base layer 14 and the second base layer 16 are stacked on the first principal surface 12a. The first base layer 14 is a layer made of an AlN-based semiconductor material and is, for example, an AlN layer gown at a high temperature (e.g. HT-AlN). The second base layer 16 is a layer made of an AlGaN-based semiconductor material and is, for example, an undoped AlGaN (u-AlGaN) layer.

The substrate 12, the first base layer 14, and the second base layer 16 function as a foundation (template) layer to form the n-type clad layer 18 and the layers above. These layers also function as a light extraction substrate for extracting the deep ultraviolet light emitted by the active layer 20 outside and transmit the deep ultraviolet light emitted by the active layer 20. It is desirable that the first base layer 14 and the second base layer 16 be made of an AlGaN-based or AlN-based material having an AlN ratio higher than that of the active layer 20 so as to increase the transmissivity for the deep ultraviolet light emitted by the active layer 20. It is further desirable that the first base layer 14 and the second base layer 16 be made of a material having a lower refractive index than the active layer 20. It is also desirable that the first base layer 14 and the second base layer 16 be made of a material having a higher refractive index than the substrate 12. Given, for example, that the substrate 12 is a sapphire substrate (the refractive index n₁=about 1.8) and the active layer 20 is a made of an AlGaN-based semiconductor material (the refractive index n₃=about 2.4-2.6), it is desirable that the first base layer 14 and the second base layer 16 be made of an AlN layer (the refractive index n₂=about 2.1) or an AlGaN-based semiconductor material (the refractive index n₂=about 2.2-2.3) having a relatively higher AlN composition ratio (the refractive index n₂=about 2.2-2.3).

The n-type clad layer 18 is an n-type semiconductor layer provided on the second base layer 16. The n-type clad layer 18 is made of n-type AlGaN-based semiconductor material. For example, the n-type clad layer 18 is an AlGaN layer doped with silicon (Si) as an n-type impurity. The composition ratio of the n-type clad layer 18 is selected to transmit the deep ultraviolet light emitted by the active layer 20. For example, the n-type clad layer 18 is formed such that the molar fraction of AlN is 40% or higher, and, preferably, 50% or higher. The n-type clad layer 18 has a band gap larger than the wavelength of the deep ultraviolet light emitted by the active layer 20. For example, the n-type clad layer 18 is formed to have a band gap of 4.3 eV or larger. The n-type clad layer 18 has a thickness of about 100 nm-300 nm. For example, the n-type clad layer 18 has a thickness of about 200 nm.

The active layer 20 is formed in a partial region on the n-type clad layer 18. The active layer 20 is made of an AlGaN-based semiconductor material and has a double heterojunction structure by being sandwiched by the n-type clad layer 18 and the electron block layer 22. The active layer 20 may form a monolayer or multilayer quantum well structure. The quantum well structure like this can be formed by building a stack of a barrier layer made of n-type AlGaN-based semiconductor material and a well layer made of undoped AlGaN-based semiconductor material. To output deep ultraviolet light having a wavelength of 355 nm or shorter, the active layer 20 is formed to have a band gap of 3.4 eV or larger. For example, the AlN composition ratio of the active layer 20 is selected so as to output deep ultraviolet light having a wavelength of 310 nm or shorter.

The electron block layer 22 is formed on the active layer 20. The electron block layer 22 is made of a p-type AlGaN-based semiconductor material. For example, the electron block layer 22 is an AlGaN layer doped with magnesium (Mg) as a p-type impurity. The electron block layer 22 is formed such that the molar fraction of AlN is 40% or higher, and, preferably, 50% or higher. The electron block layer 22 may be formed such that the molar fraction of AlN is 80% or higher or may be made of an AlN-based semiconductor material that does not substantially contain GaN. The electron block layer 22 has a thickness of about 1 nm-10 nm. For example, the electron block layer 22 has a thickness of about 2 nm-5 nm.

The p-type clad layer 24 is formed on the electron block layer 22. The p-type clad layer 24 is a layer made of a p-type AlGaN-based semiconductor material and is exemplified by a Mg-doped AlGaN layer. The composition ratio of the p-type clad layer 24 is selected such that the molar fraction of AlN in the p-type clad layer 24 is lower than that of the electron block layer 22. The p-type clad layer 24 has a thickness of about 300 nm-700 nm. For example, the p-type clad layer 24 has a thickness of about 400 nm-600 nm.

The p-type contact layer 26 is formed on the p-type clad layer 24. The p-type contact layer 26 is made of a p-type AlGaN-based semiconductor material, and the composition ratio of the p-type contact layer 26 is selected such that the Al content percentage thereof is lower than that of the electron block layer 22 or the p-type clad layer 24. It is preferable that the molar fraction of AlN in the p-type contact layer 26 is 20% or lower, and it is more preferable that the molar fraction of AlN is 10% or lower. The p-type contact layer 26 may be made of a p-type GaN-based semiconductor material that does not substantially contain AlN. By configuring the molar fraction of AlN in the p-type contact layer 26 to be small, proper ohmic contact with the p-side electrode 28 is obtained. The small AlN molar fraction can also reduce the bulk resistance of the p-type contact layer 26 and improve the efficiency of injecting carriers into the active layer 20.

The p-side electrode 28 is provided on the p-type contact layer 26. The p-side electrode 28 is made of a material capable of establishing ohmic contact with the p-type contact layer 26. For example, the p-side electrode 28 is formed by a nickel (Ni)/gold (Au) stack structure. For example, the thickness of the Ni layer is about 60 nm, and the thickness of the Au layer is about 50 nm.

The n-type contact layer 32 is provided in an exposed region on the n-type clad layer 18 where the active layer 20 is not provided. The n-type contact layer 32 may be made of an AlGaN-based semiconductor material or a GaN-based semiconductor material of an n-type having a composition ratio selected such that the Al content percentage thereof is lower than that of the n-type clad layer 18. It is preferable that the molar fraction of AlN in the n-type contact layer is 20% or lower, and it is more preferable that the molar fraction of AlN is 10% or lower.

The n-side electrode 34 is provided on the n-type contact layer 32. For example, the n-side electrode 34 is formed by a titanium (Ti)/Al/Ti/Au stack structure. For example, the thickness of the first Ti layer is about 20 nm, the thickness of the Al layer is about 100 nm, the thickness of the second Ti layer is about 50 nm, and the thickness of the Au layer is about 100 nm.

The light extraction layer 40 is provided on the second principal surface 12b of the substrate 12. Therefore, the light extraction layer 40 is provided opposite to the active layer 20, sandwiching the substrate 12. The light extraction layer 40 is made of a material having a lower refractive index than the active layer 20 and a higher refractive index than the substrate 12 for the wavelength of the deep ultraviolet light emitted by the active layer 20. Given, for example, that the substrate 12 is a sapphire substrate (the refractive index n₁=about 1.8) and the active layer 20 is a made of an AlGaN-based semiconductor material (the refractive index n₃=about 2.4-2.6), it is desirable that the light extraction layer 40 be made of AlN (the refractive index n₄=about 2.1) or an AlGaN-based semiconductor material having a relatively higher AlN composition ratio (the refractive index n₂=about 2.2-2.3). The light extraction layer 40 may be silicon nitride (SiN, the refractive index n₄=about 1.9-2.1).

It is desirable that the light extraction layer 40 is made of a material having a high transmissivity for the deep ultraviolet light emitted by the active layer 20. It is desirable that the absorption coefficient is 5×10⁴/cm or smaller or, more preferably, 1×10⁴/cm or smaller. For example, the absorption coefficient of the AlN layer for the deep ultraviolet light having a wavelength of 280 nm is 1×10²/cm, and the AlGaN layer having a AlN composition ratio of about 40% is 4×10⁴/cm. By using an AlGaN-based semiconductor material having a lower AlN composition ratio, the light extraction layer 40 having a lower absorption coefficient is realized.

By selecting a material of the light extraction layer 40 having such an absorption coefficient, loss resulting from absorption by the light extraction layer 40 is reduced and the light extraction efficiency is prevented from being lowered due to absorption by the light extraction layer 40 even when the thickness t of the light extraction layer 40 is configured to be 50 nm or larger. More specifically, the attenuation rate of the light intensity of the deep ultraviolet light as it is repeatedly reflected between the second principal surface 12b and a light extraction surface 40b to reciprocate once or multiple times inside the light extraction layer 40 can be configured to be 50% or smaller or, more preferably, 10% or smaller. For example, by configuring the light extraction layer 40 to have a thickness t=50 nm by using a material having an absorption coefficient of 4×10⁴/cm, the attenuation rate occurring when the light reciprocates once in the light extraction layer 40 will be 40%. Further, when the thickness t is configured such that t=50 nm by using a material having an absorption coefficient of 1×10⁴/cm, the attenuation rate occurring when the light reciprocates once in the light extraction layer 40 will be 10%.

The light extraction layer 40 has a light extraction surface 40b opposite to the second principal surface 12b. A micro-asperity structure (texture structure) 42 of a submicron or submillimeter scale is formed on the light extraction surface 40b. By forming an asperity structure on the light extraction surface 40b, reflection or total reflection on the light extraction surface 40b is inhibited and the light extraction efficiency is increased. The light extraction surface 40b (texture surface) formed with the asperity structure 42 may be coated with a material having a lower refractive index than the light extraction layer 40. For example, the light extraction surface 40b may be coated with silicon oxide (SiO₂) or amorphous fluororesin. In one variation, the light extraction surface 40b may not be provided with the asperity structure 42, and the light extraction surface 40b may be configured as a flat surface.

A description will now be given of a method of manufacturing the deep ultraviolet light emitting device 10. First, the first base layer 14, the second base layer 16, the n-type clad layer 18, the active layer 20, the electron block layer 22, the p-type clad layer 24, and the p-type contact layer 26 are stacked successively on the substrate 12. The second base layer 16, the n-type clad layer 18, the active layer 20, the electron block layer 22, the p-type clad layer 24, and the p-type contact layer 26 made of an AlGaN-based semiconductor material or a GaN-based semiconductor material can be formed by a well-known epitaxial growth method such as the metalorganic chemical vapor deposition (MOVPE) method and the molecular beam epitaxial (MBE) method.

Subsequently, portions of the active layer 20, the electron block layer 22, the p-type clad layer 24, and the p-type contact layer 26 stacked on the n-type clad layer 18 are removed to expose a partial region of the n-type clad layer 18. For example, portions of the active layer 20, the electron block layer 22, the p-type clad layer 24, and the p-type contact layer 26 may be removed by forming a mask, avoiding a partial region on the p-type contact layer 26 and performing reactive ion etching or dry etching using plasma, thereby exposing a partial region of the n-type clad layer 18.

The n-type contact layer 32 is then formed on the partial region of the n-type clad layer 18 exposed. The n-type contact layer 32 can be formed by a well-known epitaxial growth method such as the metalorganic chemical vapor deposition (MOVPE) method and the molecular beam epitaxial (MBE) method. Subsequently, the p-side electrode 28 is formed on the p-type contact layer 26, and the n-side electrode 34 is formed on the n-type contact layer 32. The metal layers forming the p-side electrode 28 and the n-side electrode 34 may be formed by a well-known method such as the MBE method.

The light extraction layer 40 is then formed on the second principal surface 12b of the substrate 12. The light extraction layer 40 is made of an undoped AlGaN-based semiconductor material or AlN and can be formed by a well-known epitaxial growth method such as the metalorganic chemical vapor deposition (MOVPE) method and the molecular beam epitaxial (MBE) method. The asperity structure 42 of the light extraction surface 40b can be formed by anisotropical etching using an alkaline solution such as potassium hydroxide (KOH) or dry etching via a nanoimprinted mask. A coating layer of silicon oxide or amorphous fluororesin may further be provided on the asperity structure 42. The deep ultraviolet light emitting device 10 shown in FIG. 1 is manufactured through the steps described above.

The steps in the manufacturing method described above may be executed in the order described above or in a different order. For example, the light extraction layer 40 may be formed on the second principal surface 12b before forming the layers on the first principal surface 12a. Still alternatively, the light extraction layer 40 may be formed on the second principal surface 12b in the middle of forming the layers on the first principal surface 12a.

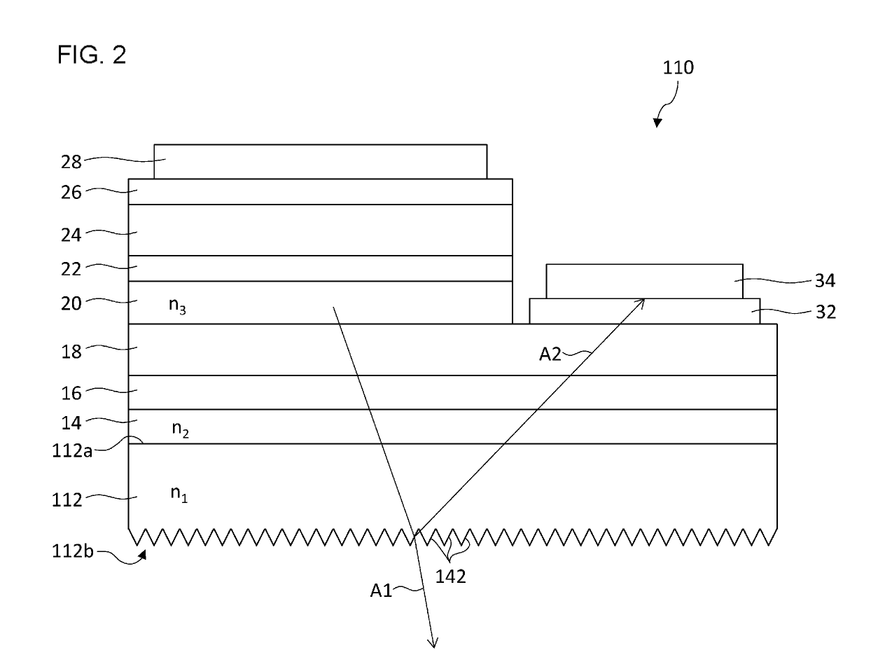

A description will now be given of an advantage achieved by the deep ultraviolet light emitting device 10 according to the embodiment. FIG. 2 schematically shows a deep ultraviolet light emitting device 110 according to a comparative example. The deep ultraviolet light emitting device 110 according to the comparative example differs from the embodiment in that the light extraction layer 40 is not provided on a second principal surface 112b of a substrate 112 and the second principal surface 112b is the light extraction surface. A portion A1 of the deep ultraviolet light traveling from the active layer 20 to the substrate 112 is extracted outside the deep ultraviolet light emitting device 110 from the second principal surface 112b, but another portion A2 is reflected or scattered by the second principal surface 112b before returning to the first principal surface 112a. Since the refractive index n₁ of the substrate 112 is smaller than the refractive index n₂ of the first base layer 14, the return light A2 from the substrate 112 propagates through the layers provided above the first principal surface 112a without being totally reflected by the first principal surface 112a. As the return light A2 arrives at the p-type contact layer 26 and the p-side electrode 28 above the n-side electrode 34 and the active layer 20, the return light A2 is absorbed by these layers and the electrodes and causes a loss. Thus, according to the comparative example, the light arrives at the second principal surface 112b of the substrate 112 but the deep ultraviolet light returning from the second principal surface 112b to the interior may not be extracted outside properly.

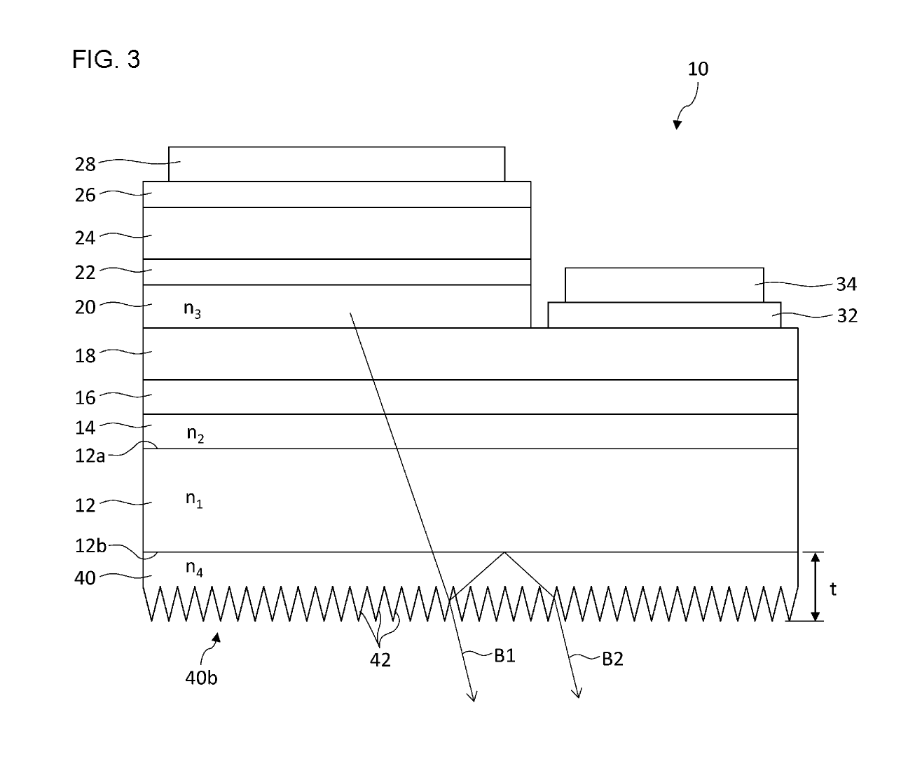

FIG. 3 schematically shows the benefit provided by the deep ultraviolet light emitting device 10 according to the embodiment. According to the embodiment, the refractive index n₄ of the light extraction layer 40 is higher than the refractive index n₁ of the substrate 12 so that the deep ultraviolet light traveling from the active layer 20 to the substrate 12 arrives at the light extraction layer 40 without being totally reflected by the second principal surface 12b. A portion B1 of the deep ultraviolet light propagating in the light extraction layer 40 is extracted outside the deep ultraviolet light emitting device 10 from the light extraction surface 40b, but another portion B2 is reflected or scattered by the light extraction surface 40b and returns to the second principal surface 12b. Since the refractive index n₄ of the light extraction layer 40 is higher than the refractive index n₁ of the substrate 12, the portion B2 of the deep ultraviolet light incident from the light extraction layer 40 on the second principal surface 12b in a certain angular range is reflected or totally reflected by the second principal surface 12b before traveling to the light extraction surface 40b again. A portion of the portion B2 of the deep ultraviolet light reflected by the second principal surface 12b and traveling to the light extraction surface 40b is extracted outside the deep ultraviolet light emitting device 10 from the light extraction surface 40b. Thus, according to this embodiment, a portion of the deep ultraviolet light returning from the light extraction surface 40b to the substrate can be guided toward the light extraction surface 40b again to exit outside. Therefore, the light extraction efficiency for the deep ultraviolet light is increased.

According to this embodiment, the asperity structure 42 is formed on the light extraction layer 40 instead of the substrate 12 made of sapphire. Therefore, a texture structure having a high aspect ratio can be formed relatively easily. Sapphire, which is used for the substrate 12, is a hard material that cannot be etched easily (i.e., is a material having a low etching rate). It is therefore difficult to form a structure having a high aspect ratio by dry etching the substrate 12 via a nanoimprinted mask. It is generally known that the light extraction efficiency of a texture structure formed on a light extraction surface is increased by increasing the aspect ratio. A texture structure directly formed on a sapphire substrate may have a low aspect ratio. Therefore, an asperity structure having an aspect ratio sufficient to increase the light extraction efficiency may not be formed. Meanwhile, according to this embodiment, the asperity structure 42 is formed on the light extraction layer 40 made of a material having a higher etching rate than sapphire. It is therefore easier to form the asperity structure 42 of a high aspect ratio than in the case of sapphire. Consequently, the benefit of improving the light extraction efficiency due to the asperity structure 42 is enhanced.

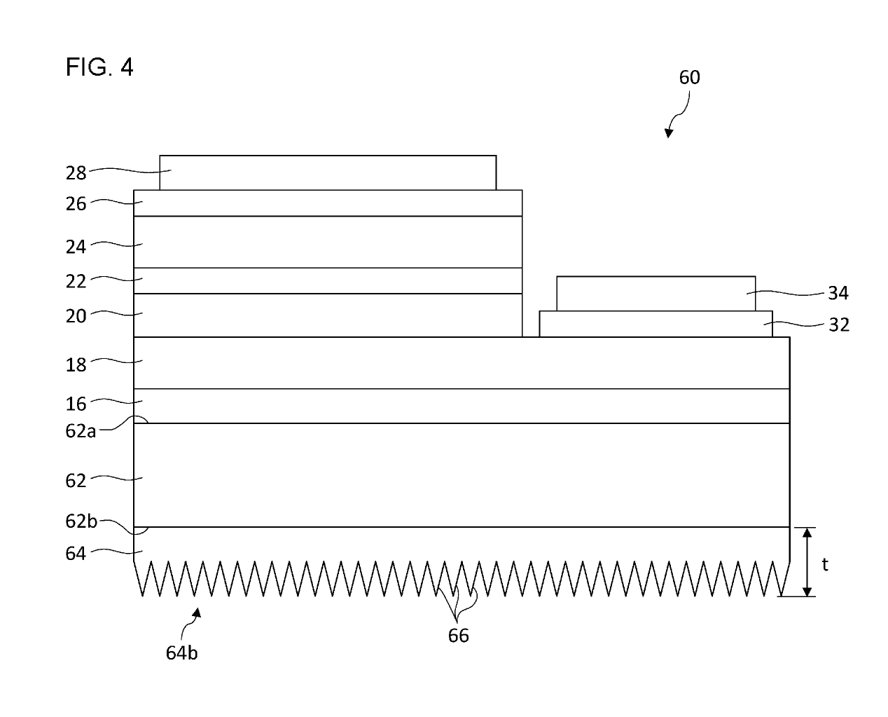

FIG. 4 is a cross sectional view schematically showing a configuration of a deep ultraviolet light emitting device 60 according to a variation. The deep ultraviolet light emitting device 60 according to the variation differs from the embodiment described above in that an aluminum nitride (AlN) substrate 62 is provided instead of a sapphire substrate 12.

The deep ultraviolet light emitting device 60 includes a substrate 62, a second base layer (base layer) 16, an n-type clad layer 18, an active layer 20, an electron block layer 22, a p-type clad layer 24, a p-type contact layer 26, a p-side electrode 28, an n-type contact layer 32, an n-side electrode 34, and a light extraction layer 64.

The substrate 62 is an AlN substrate. The base layer 16 made of an undoped AlGaN-based semiconductor material is provided on a first principal surface 62a of the substrate 62. The light extraction layer 64 made of an AlGaN-based semiconductor material having a higher refractive index than the AlN substrate 62 is provided on a second principal surface 62b of the substrate 62 opposite to the first principal surface 62a. The light extraction layer 64 is made of an AlGaN-based semiconductor material having a higher AlN composition ratio than the active layer 20. The refractive index of the light extraction layer 64 for the deep ultraviolet light emitted by the active layer 20 is lower than that of the active layer 20. The light extraction layer 64 has a light extraction surface 64b opposite to the second principal surface 62b. A micro-asperity structure 66 of a submicron or submillimeter scale is formed on the light extraction surface 64b.

It is desirable that the light extraction layer 64 is made of a material having a high transmissivity for the deep ultraviolet light emitted by the active layer 20. It is desirable that the absorption coefficient is 5×10⁴/cm or smaller or, more preferably, 1×10⁴/cm or smaller. By selecting a material having such an absorption coefficient, loss resulting from absorption by the light extraction layer 64 is reduced and the light extraction efficiency is prevented from being lowered due to absorption by the light extraction layer 64 even when the thickness t of the light extraction layer 64 is configured to be 50 nm or larger.

According to this variation, the same advantage as described above of the embodiment is provided.

Described above is an explanation based on an exemplary embodiment. The embodiment is intended to be illustrative only and it will be understood by those skilled in the art that various design changes are possible and various modifications are possible and that such modifications are also within the scope of the present invention.

What is claimed is:

1. A deep ultraviolet light emitting device comprising:
a substrate having a first principal surface and a second principal surface opposite to the first principal surface;
an active layer provided on the first principal surface of the substrate configured to emit a deep ultraviolet light; and
a light extraction layer provided on the second principal surface of the substrate and made of a material having a refractive index for the deep ultraviolet light emitted by the active layer higher than that of the substrate and lower than that of the active layer.

2. The deep ultraviolet light emitting device according to claim 1, further comprising:
a base layer provided between the first principal surface of the substrate and the active layer and made of a material having a refractive index for the deep ultraviolet light emitted by the active layer higher than that of the substrate and lower than that of the active layer.

3. The deep ultraviolet light emitting device according to claim 1, wherein the light extraction layer is made of a material having an absorption coefficient of 5×10⁴/cm or smaller for the deep ultraviolet light emitted by the active layer.

4. The deep ultraviolet light emitting device according to claim 1, wherein a thickness of the light extraction layer is 50 nm or larger.

5. The deep ultraviolet light emitting device according to claim 1, wherein the light extraction layer has a light extraction surface formed with a micro-asperity structure.

6. The deep ultraviolet light emitting device according to claim 1, wherein the light extraction layer is an aluminum gallium nitride (AlGaN)-based semiconductor material layer or an aluminum nitride (AlN) layer.

7. The deep ultraviolet light emitting device according to claim 1, wherein the light extraction layer is made of aluminum gallium nitride (AlGaN).

8. The deep ultraviolet light emitting device according to claim 7, wherein the substrate is made of sapphire (Al₂O₃).

9. The deep ultraviolet light emitting device according to claim 1, wherein the substrate is made of aluminum nitride (AlN).

10. The deep ultraviolet light emitting device according to claim 1, wherein the substrate is made of sapphire (Al₂O₃), and the light extraction layer is made of aluminum nitride (AlN).

11. The deep ultraviolet light emitting device according to claim 1, wherein the substrate is made of sapphire (Al₂O₃), and the light extraction layer is made of silicon nitride (SiN).
